(19) United States
(12) Patent Application Publication
(10) Pub. No.: US 2008/0054924 A1
(43) Pub. Date: Mar. 6, 2008

(54) Contact for interconnect system

(76) Inventor: Wei Kuong Foong, Selangor Darul Ehsan (MY)

Correspondence Address: DONN K. HARMS;PATENT & TRADEMARK LAW CENTER, SUITE 100, 12702 VIA CORTINA, DEL MAR, CA, 92014, US

(21) Appl. No.: 11/796,527

(22) Filed: Apr. 26, 2007

(30) Foreign Application Priority Data
Sep. 5, 2006 (MY) PI 20064086

(51) Int. Cl. G01R 31/28

(52) U.S. Cl. 324/755

(57) ABSTRACT

The present invention generally relates to testing of IC devices, more specifically to a contact (11) for a test socket (1) for interfacing leads (21) of the IC devices (2) with a printed circuit board (3) of a tester. The contact (11) comprises a contact body (12), a first arm (13) adapted for electronically engaging the leads (21) and a second arm (14) adapted for electronically engaging the corresponding terminals (31) on the printed circuit board (3). The first engaging means (15) is a wiping means for improved wiping action between the contact (11) and the leads (21). The wiping means enable a single contact to be used for various IC devices and also protects the leads (21) and contacts (11) of the test socket (1) from damage and extensive wear.

### 1. TECHNICAL FIELD OF THE INVENTION

This application claims the benefit of Malaysian Priority Document (Malaysian patent application no. PI 2006 4086, filed Sep. 5, 2006. The present invention generally relates to testing of integrated circuits (herein after referred to as IC). More particularly, the device relates to an improved contact for a test socket which interfaces with leads of IC devices with a printed circuit board of a tester, which protects both the IC leads and contacts of the test socket from damage and extensive wear.

### 2. BACKGROUND OF THE INVENTION

IC devices have many applications in today's industry. In order to provide for efficient and uninterrupted operation, such devices must be tested to ensure each device meets the high quality required of the electronics industry. Such testing and burn-in of the IC device typically requires the devices to be actuated by engagement of their leads, with corresponding contacts of a test socket. The contacts of the test socket, in turn, electronically communicate with terminals of a printed circuit board of a test socket or tester which is adapted to test the IC device in question. It is desirable that such IC devices may be tested in both a manual mode and automatic mode of testing. In methods known in the art, “pick and place” or gravity feed handling employs the modification of existing manual test sockets, in order to construct dedicated test sockets that are specifically adapted to interface with the tester.

This type of test socket typically comprises a socket housing and a cover assembly. The socket housing is provided with an array of compliant contacts adapted to electronically engage the IC, while the cover assembly is hinged at one edge of the socket housing. When a device is in the test socket, the cover assembly is latched at an edge opposite that of the hinge. The IC devices are aligned within the socket housing by various means to guide the leads into engagement with the corresponding contacts within the test socket cavity.

In conventional practice, contacts in such test sockets are generally formed with S-shaped arms. The extremities of the upper and lower arms of the S-shaped arm act as contacts that interconnect the leads of the IC with the printed circuit board of the tester. It is within the socket housing that the tips of the contacts are held. The contact is profiled appropriately for interfacing with the device otherwise engagement of the contact tip and the pad/lead will not effect the desired wiping action. One of the main drawback of the conventional contact is the thickness is the same throughout the piece.

New IC devices such as the QFN/MLP have pad/lead and in the molding process, often have excessive moulding flash or a solder mask as impediments to good electrical contact. This often interferes with the contact probe thereby causing a test failure. A narrower solder mask in certain IC package designs also provides impediments to good contact and increases test failure due to the narrower test pads. In this respect IC devices with these over moulding pad/lead configurations will not be able to be tested because poor contact due to the conventional contact pin width matches the pad/lead width and thus will not be able to penetrate the narrower sunken or flat devices pad/lead for a good test.

As such, the test yield is lost and retest is needed. In order to retest this narrower sunken or flat devices pad/lead, the contact needs to be changed to a thinner conventional contact and a corresponding socket. Thus during testing, especially testing of IC devices having different types of pad/lead configurations, different contacts have to be used for each device which necessitates employment of three different contacts having different profiles and configuration. This only complicates matters and increases testing time. Therefore, there arises an unmet need for a new contact which can serve a plurality of IC devices having various pad/lead profiles and configurations. This has been the main object of the present invention.

The present invention discloses an improved test contact which functions to electronically interface the leads of an IC device to be tested, with corresponding terminals on a printed circuit board. The device according to the present invention enables testing of similar pad configurations without changing the whole socket.

### 3. SUMMARY OF THE INVENTION

Accordingly, it is the primary aim of the present to provide a contact (11) for electronically interfacing leads (21) of integrated circuit devices (2) to be tested, with corresponding terminals (31) on a printed circuit board (3).

It is another object of the present invention to provide a contact that is mechanically and thermally stable for acceptably high accuracy testing and suitable for various pad/lead configurations.

It is yet another object of the present invention to provide a contact having an improved wiping action with the leads for improved penetration for better contact and resistance against wear and tear.

These and other objects of the present invention are accomplished by, In a test socket (1) for testing integrated circuit devices (2) or the like, a contact (11) is provided for electronically interfacing leads (21) of said integrated circuit devices (2) to be tested, with corresponding terminals (31) on a printed circuit board (3), the contact (11) featuring a contact body (12); a first arm (13) adapted for electronically engaging said leads (21); the first arm (13) being provided with a first engaging means (15), and a second arm (14) adapted for electronically engaging the corresponding terminals (31) on the printed circuit board (3); the second arm (14) being provided with a second engaging means (16), the first arm (13) and the second arm (14) being located at opposing extremities of said contact body (12), characterized by said first engaging means (15) being provided with a wiping means for improved wiping action with said leads (21).

The present invention generally relates to a contact (11) for a test socket for interfacing leads of IC devices with a printed circuit board of a test socket during testing. Generally the contact (11) has a contact body (12), a first arm (13) and a second arm (14) that combine to look substantially like the letter “S”. The first arm (13) is adapted for electronically engaging leads (21) of IC devices to be tested. For improved engagement, the first arm (13) is provided with a first engaging means (35) having a wiping means in the form of tip projecting from a top most portion of the first arm (13) as seen in FIG. 2a.

The second arm (14) is provided with a second engaging means (16), which is adapted for electronically engaging the contact (11) to corresponding terminals (31) on the printed circuit board (3) of the test socket (1). The extended tip (25) of the first engaging means (15) provides improved wiping action with the IC leads (21), and in an especially preferred mode of the device, has a thickness less than that of the body of the contact (11) thereby providing means to avoid electrical contact impediments engaged or formed on, or in-between said leads. The curved exterior surfaces of contact (11) along the extended tip (25) and both arms of the body, also help protect the leads (21) and contacts (31) of the test socket from damage and extensive wear. A planar contact section (19) positioned to operatively engage with the lead (21) provides an especially good contact therefor. Further, the thickness of the extended tip (25) at least at the contact section (19) is best if thinner than the thickness of the first arm as best shown in FIG. 2b. Currently the preferred ratios of the thickness of the tip (25) or at least the contact section (19) is from 20-60% of the thickness of the first arm (13) of the contact (11) thereby allowing the contact (11) to adapt to leads (21) of varying width without having to change the contact

### 4. BRIEF DESCRIPTION OF THE DRAWINGS

Other aspects of the present invention and their advantages will be discerned after studying the Detailed Description in conjunction with the accompanying drawings in which:

FIG. 1 showing general view of the contact as installed in the test socket.

FIG. 2a showing side view of the disclosed device with the top projecting from the first arm and a contact section of the tip having a generally planar shape to insure good communication with the leads.

FIG. 2b depicts an end view of the contact and shows the preferred mode with the tip having a decreased thickness from that of the contact itself.

FIG. 3 showing the test socket in operation showing the position of the contact of the present invention.

### 5. DETAILED DESCRIPTION OF THE PREFERRED EMBODIMENTS OF THE INVENTION

Referring now to FIG. 1 showing general view of the contact according to one favored embodiment of the present invention installed in the test socket (1). According to the broadest aspect of the present invention the contact (11) comprises a contact body (12), a first arm (13) and a second arm (14). The contact body (12) is substantially an S-shaped piece of conductive material such as metal or precious metal having two identical but opposing arms, a first arm (13) and a second arm (14). It is made from a sheet having the required thickness, profile and stamped to shape. The loops that are formed in between the arms are adapted for engaging an elastomer for holding the contact (11) in position during testing.

The first arm (13) is adapted for electronically engaging the leads (21) of the IC devices (2) to be tested to the contact (11). The tip of the first arm (13) has a first engaging means (15) that is provided with a wiping means for improved wiping action with the leads (21). A good wiping action is achieved when the contact pressure between the leads (21) and the wiping means is just right and is provided by the biasing action of the elastomer (23) to impart the desired contact for a good electric flow but not excessive to be detrimental to the contact (31) as well as the leads (21) of the IC devices. Preferably the wiping means is made from a resilient material such as Beryllium Copper, to be able to vary and compensate the contact pressure to accommodate for the different types of lead profiles and configurations.

The second arm (14) adapted for electronically engaging the contact (11) with the corresponding terminals (31) on the printed circuit board (3) of the tester. The second arm (14) is provided with a second engaging means (16) which extending around the exterior edge of the of the second arm (14). Unlike the first arm (13) that is provided with the wiping means (15) in the form of an extended tip (25), the second arm is not provided with such an extended tip. Instead the rounded contact surface on the exterior edge of the second arm (14) providing the second contact means (16) also provides means to regulate and compensate contact pressure by self-adjusting its position with respect to the profile and configuration of the pad/leads.

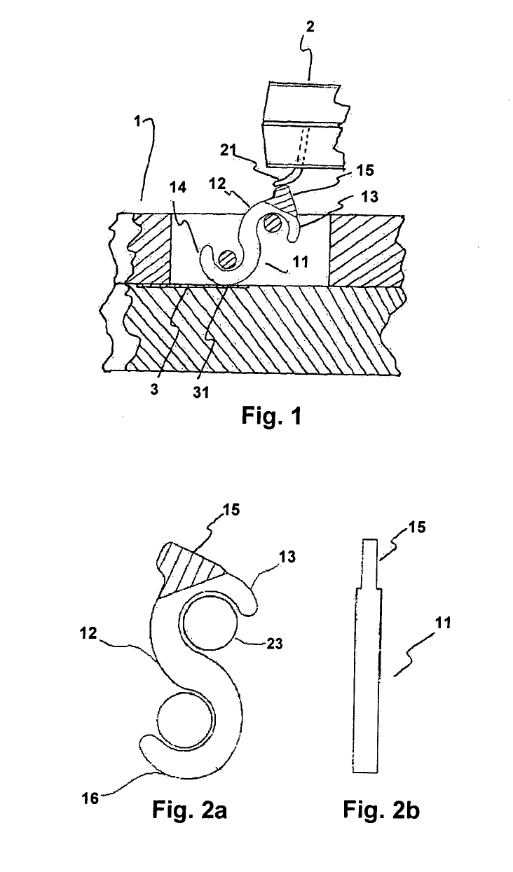

Referring now to FIG. 2a showing side view and FIG. 2b showing front view of the contact according to one embodiment of the present invention. The contact (11) according to one embodiment of the present invention is an S-shaped piece of conductive material. The bent portion of the S-section acting as the arms that provides contact from the pad/leads of the IC devices to the printed circuit board of the tester. The contacting portion of the first arm (13) acting as a first engaging means is provided with the wiping means (15) by the extended tip (25) projecting from the outside edge of the first arm (13). In the preferred mode of the device, the extended tip (25) has a thickness which is less than the thickness of the first arm (13) and/or the thickness of the contact body (12). The narrower configuration provides means to accommodate a plurality of different types of lead (21) profiles and configurations by electrically engaging the lead (21) along a narrower contact edge which allows electrical contact with narrower leads while allowing contact with wider leads (21) which might have depressions or solder, or other impediments that would render a wider edge out of proper electrical contact. Further advantageously the extended tip (25) is of homogenous material and is manufactured integral with the contact body (12). Alternatively, the extended tip may be made from a different material brazed onto the first arm (13).

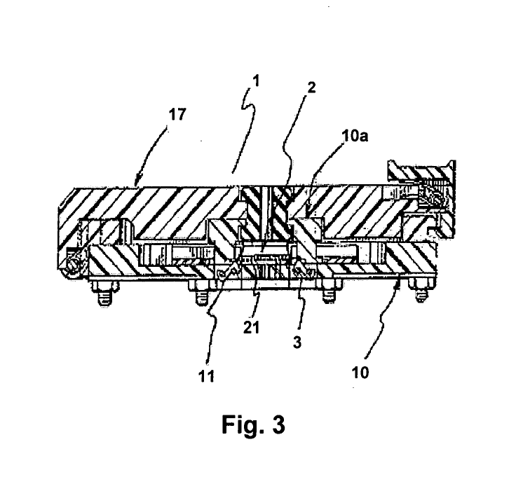

Referring now to FIG. 3 showing the test socket in operation showing the position of the contact of the present invention. The test socket (1) basically has two components, a socket (10) that is provided with a test cavity (10a) and a cover (17). The contact (11) is placed in the test cavity (10a) of the socket (10) to interconnect the printed circuit board (3) of the tester to the leads (21) of the IC devices (2). The cover (17) is then put into the close position to commence testing. Using the extended tip (25) having a thickness less than the thickness of the first arm (13) or the thickness of the contact body (12) allows for the employment of only one type of contact to accommodate numerous different types of IC devices pad/lead and pitches. This reduces stock and eases inventory control since only one type of contact needs to be stocked. In daily operation, downtime during testing may be considerably reduced.

While the preferred embodiment of the present invention and their advantages have been disclosed in the above Detailed Description, the invention is not limited thereto but only by the scope of the appended claim.

What is claimed is:

1. In a test socket (1) for testing integrated circuit devices (2) or the like, a contact (11) is provided for electronically interfacing leads (21) of said integrated circuit devices (2) to be tested, with corresponding terminals (31) on a printed circuit board (3), said contact (11) comprising:
a contact body (12);
a first arm (13) adapted for electronically engaging said leads (21);
said first arm (13) being provided with a first engaging means (15), and
a second arm (14) adapted for electronically engaging said corresponding terminals (31) on said printed circuit board (3);
said second arm (14) being provided with a second engaging means (16); and
said first arm (13) and said second arm (14) being located at opposing extremities of said contact body (12), characterized by said first engaging means (15) being provided with a wiping means for improved wiping action with said leads (21).

2. A contact (11) for a test socket (1) as claimed in claim 1, further characterized by said wiping means being a pointed tip extending from a top most portion of said first arm (13).

3. A contact (11) for a test socket (1) as claimed in claim 2, further characterized by said pointed tip being integral with said first arm (13).

4. A contact (11) for a test socket (1) as claimed in claim 2, further characterized by said pointed tip having a reduced thickness, said reduced thickness being less than that of said contact body (12).

5. A contact (11) for a test socket (1) as claimed in claim 2, further characterized by said pointed tip being made from a different material as that of said first arm (13).

6. A contact (11) for a test socket (1) as claimed in claim 2, further characterized by said pointed tip being brazed onto said first arm (13).

7. A contact (11) for a test socket (1) as claimed in claim 2, further characterized by said pointed tip having a planar edge portion, said planar edge portion positioned to contact one of said leads.

8. A contact (11) for a test socket (1) as claimed in claim 2, further characterized by said pointed tip, at least along said planar edge portion, having a reduced thickness, said reduced thickness being less than that of said contact body (12).

9. A contact (11) for a test socket (1) as claimed in claim 8, further characterized by said reduced thickness along said planar edge providing means to avoid contact impediments engaged or formed on or in-between said leads.

10. A contact (11) for a test socket (1) as claimed in claim 4 wherein said reduced thickness, is of a thickness between 20 to 60 percent of said thickness of said contact body.

11. A contact (11) for a test socket (1) as claimed in claim 9 wherein said reduced thickness, is of a thickness between 20 to 60 percent of said thickness of said contact body.
